(19) United States
(12) Patent Application Publication
(10) Pub. No.: US 2026/0040700 A1
(43) Pub. Date: Feb. 5, 2026

(54) IMAGE SENSOR

(71) Applicant: Samsung Electronics Co., Ltd., Suwon-si (KR)

(72) Inventors: Kyoungmok SON, Suwon-si (KR); Hyounmin BAEK, Suwon-si (KR); Youngwoo CHUNG, Suwon-si (KR)

(73) Assignee: Samsung Electronics Co., Ltd., Suwon-si (KR)

(21) Appl. No.: 19/024,302

(22) Filed: Jan. 16, 2025

(30) Foreign Application Priority Data
Aug. 2, 2024 (KR) 10-2024-0103275

(51) Int. Cl. H10F 39/18; H10F 39/00

(52) U.S. Cl. CPC H10F 39/18; H10F 39/016; H10F 39/80373; H10F 39/80377; H10F 39/811

(57) ABSTRACT

An image sensor including a first semiconductor substrate; a photoelectric conversion region within the first semiconductor substrate; a floating diffusion region within the first semiconductor substrate, the floating diffusion region storing charges transferred from the photoelectric conversion region; a transfer transistor on a front surface of the first semiconductor substrate, the transfer transistor electrically connecting the photoelectric conversion region to the floating diffusion region; a first insulating layer covering the front surface of the first semiconductor substrate and the transfer transistor; and a pixel transistor on the first insulating layer. The pixel transistor includes a thin film transistor.

### CROSS-REFERENCE TO RELATED APPLICATION

This application is based on and claims priority under 35 U.S.C. § 119 to Korean Patent Application No. 10-2024-0103275, filed on Aug. 2, 2024, in the Korean Intellectual Property Office, the disclosure of which is incorporated by reference herein in its entirety.

### BACKGROUND

The inventive concepts relate to image sensors, and more particularly, to image sensors with photodiodes.

An image sensor is a device for converting optical image signals into electrical signals. An image sensor includes a plurality of pixels, each of which receives and converts incident light into electrical signals and includes a photodiode region. Generally, a unit pixel may include a light-sensing device, such as a photodiode, and a plurality of pixel transistors. The plurality of pixel transistors may include, for example, a transfer transistor, a reset transistor, a source follower transistor, and a selection transistor, wherein the transfer transistor connects a photoelectric conversion region to a floating diffusion region.

### SUMMARY

The inventive concepts provide an image sensor with improved performance by forming a pixel transistor as a thin film transistor.

Some example of the inventive concepts provide an image sensor that includes a first semiconductor substrate; a photoelectric conversion region within the first semiconductor substrate; a floating diffusion region within the first semiconductor substrate, the floating diffusion region storing charges transferred from the photoelectric conversion region; a transfer transistor on a front surface of the first semiconductor substrate, the transfer transistor electrically connecting the photoelectric conversion region to the floating diffusion region; a first insulating layer covering the front surface of the first semiconductor substrate and the transfer transistor; and a pixel transistor on the first insulating layer. The pixel transistor includes a thin film transistor.

Some example embodiments of the inventive concepts further provided an image sensor that includes a first semiconductor substrate; a photoelectric conversion region within the first semiconductor substrate; a floating diffusion region within the first semiconductor substrate, the floating diffusion region storing charges transferred from the photoelectric conversion region; a transfer transistor on a front surface of the first semiconductor substrate, the transfer transistor electrically connecting the photoelectric conversion region to the floating diffusion region; a first insulating layer covering the front surface of the first semiconductor substrate and the transfer transistor; and a plurality of pixel transistors on the first insulating layer, the plurality of pixel transistors each consisting of a thin film transistor. The plurality of pixel transistors include a first pixel transistor and a second pixel transistor, and the first pixel transistor and the second pixel transistor are different types of pixel transistors.

Some example embodiments of the inventive concepts still further provide an image sensor that includes a first stack including a first semiconductor substrate including a first surface and a second surface opposite the first surface, a photoelectric conversion region in the first semiconductor substrate, a floating diffusion region in the first semiconductor substrate and storing charges transferred from the photoelectric conversion region, a transfer transistor on a front surface of the first semiconductor substrate and electrically connecting the photoelectric conversion region to the floating diffusion region, a first insulating layer covering the front surface of the first semiconductor substrate and the transfer transistor, and a pixel transistor on the first insulating layer; and a second stack attached to the first stack and including a logic transistor that provides signals to the pixel transistor and the transfer transistor. The pixel transistor includes a thin film transistor including polysilicon.

### BRIEF DESCRIPTION OF THE DRAWINGS

Embodiments will be more clearly understood from the following detailed description taken in conjunction with the accompanying drawings in which:

FIG. 1 is a schematic perspective view of an image sensor according to some example embodiments;

FIG. 2 is a schematic cross-sectional view of an image sensor according to some example embodiments;

FIG. 3A is an enlarged cross-sectional view of region EX1 in FIG. 2;

FIG. 3B is an enlarged cross-sectional view taken along the center of region EX1 in FIG. 2 in a second direction;

FIG. 4A is an enlarged cross-sectional view of region EX2 in FIG. 2;

FIG. 4B is an enlarged cross-sectional view taken along the center of region EX2 in FIG. 2 in the second direction;

FIG. 5 is an enlarged cross-sectional view taken along the center of region EX1 in FIG. 2 in the second direction;

FIG. 6 is an enlarged cross-sectional view taken along the center of region EX1 in FIG. 2 in the second direction;

FIG. 7 is a schematic cross-sectional view of an image sensor according to some example embodiments;

FIG. 8 is an enlarged cross-sectional view of region EX3 in FIG. 7;

FIG. 9 is an enlarged cross-sectional view of region EX4 in FIG. 7;

FIGS. 10, 11, 12A, 12B, 13A, 13B, 14A, 14B, 15A, 15B, 15C, 16, 17 and 18 are cross-sectional views illustrating a method of manufacturing an image sensor, according to some example embodiments, wherein FIGS. 12A, 13A, 14A and 15A are enlarged cross-sectional views of region EX1 in FIG. 11 and FIGS. 12B, 13B, 14B, and 15B are enlarged cross-sectional views taken along the center of region EX1 in FIG. 11 in the second direction; and

FIG. 19 is a block diagram showing the configuration of an image sensor according to an embodiment.

### DETAILED DESCRIPTION

Hereinafter, embodiments are described in detail with reference to the accompanying drawings. The same reference numerals are used for the same components in the drawings and duplicate descriptions thereof are omitted.

In the following specification, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

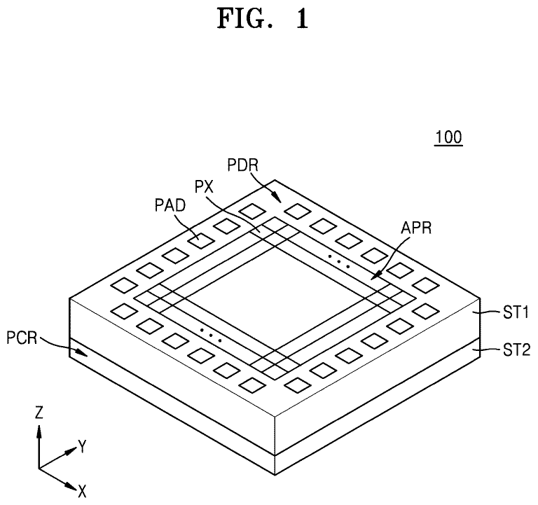

FIG. 1 is a schematic perspective view of an image sensor 100 according to some example embodiments.

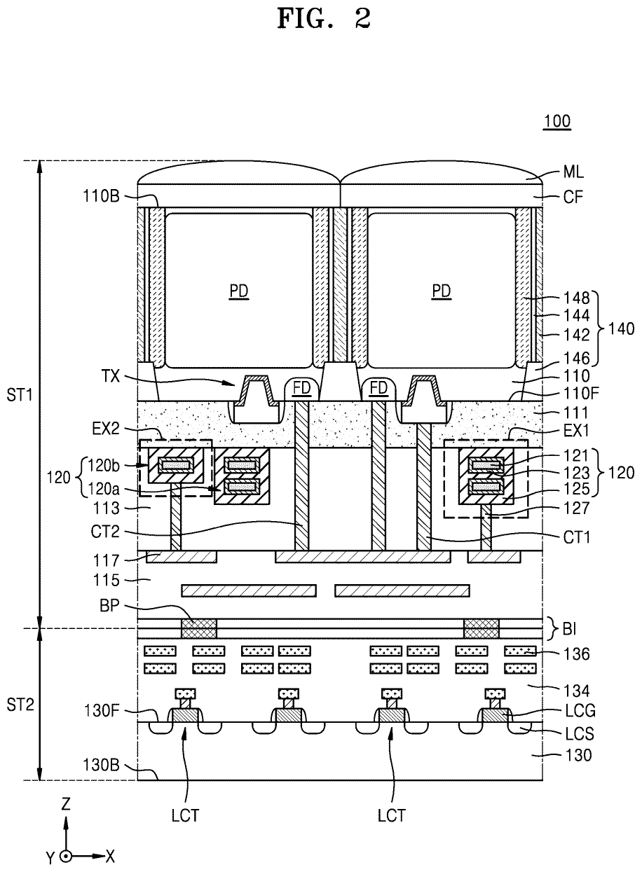

FIG. 2 is a schematic cross-sectional view of the image sensor 100 according to some example embodiments.

Referring to FIGS. 1 and 2, the image sensor 100 may include a stacked image sensor in which a first stack ST1 and a second stack ST2 are stacked in a vertical direction (Z).

In some example embodiments, an active pixel region APR may be positioned in a center portion of the image sensor 100, wherein a plurality of pixels PX may be positioned in the active pixel region APR. The plurality of pixels PX may include a region that receives light from the outside of the image sensor 100 and converts the light into electrical signals.

In some example embodiments, the plurality of pixels PX may be arranged in the first stack ST1. For example, a photoelectric conversion region PD for receiving external light and transistors constituting a pixel circuit for converting photo charges accumulated in the photoelectric conversion region PD into electrical signals may be positioned in the first stack ST1.

In some example embodiments, a pad region PDR may be disposed on at least one side of the active pixel region APR, for example, on four sides of the active pixel region APR in a plan view. The plurality of pads PAD may be positioned in the pad region PDR and may be configured to transmit and receive electrical signals to and from an external device.

In some example embodiments, a peripheral circuit region PCR may include a logic circuit block and/or a memory device. For example, the logic circuit block may include a plurality of logic transistors LCT and may provide a constant signal to each pixel PX of the active pixel region APR or may control an output signal from each pixel PX. For example, the logic transistor LCT may include at least one of a row decoder, a row driver, a column decoder, a timing generator, a correlated double sampler (CDS), an analog-to-digital converter, and an input/output (I/O) buffer.

In some example embodiments, the active pixel region APR may include the plurality of pixels PX, wherein a plurality of photoelectric conversion regions PD may be positioned in the plurality of pixel PX, respectively. For example, the plurality of pixels PX may include a first pixel, a second pixel, a third pixel, and a fourth pixel, wherein the first to fourth pixels may be arranged in a matrix shape. Each of the first through fourth pixels may include a photoelectric conversion region PD and a floating diffusion region FD.

In some example embodiments, the active pixel region APR may include the plurality of pixels PX, wherein the photoelectric conversion region PD may be positioned in each of the plurality of pixels PX. In the active pixel region APR, the plurality of pixels PX may be arranged in a matrix shape, forming columns and rows, in a first direction (X) parallel to a top surface of the first semiconductor substrate 110 and a second direction (Y) parallel to a top surface of the second semiconductor substrate 110 and perpendicular to the first direction (X). Some of the plurality of pixels PX may include optical black pixels (not shown). The optical black pixel may function as a reference pixel for the active pixel region APR and may perform a function of automatically correcting dark signals.

In some example embodiments, the first stack ST1 may include a first semiconductor substrate 110 having a front surface 110F and a back surface 110B, a photoelectric conversion region PD and a floating diffusion region FD formed inside the first semiconductor substrate 110, a transfer transistor TX and a first insulating layer 111 disposed on the front surface 110F of the first semiconductor substrate 110, a pixel transistor 120 and a second insulating layer 113 disposed on the first insulating layer 111, a third insulating layer 115 and a first wiring structure 117 disposed on the second insulating layer 113, and a color filter CF and a microlens ML disposed on the back surface 110B of the first semiconductor substrate 110.

In some example embodiments, the second stack ST2 may include a second semiconductor substrate 130 having a front surface 130F, a back (e.g., bottom) surface 130B, logic transistors LCT disposed on the front surface 130F of the second semiconductor substrate 130, a second wiring structure 136, and a fourth insulating layer 134.

In some example embodiments, the third insulating layer 115 of the first stack ST1 may face the fourth insulating layer 134 of the second stack ST2. A bonding layer BI may be positioned between the third insulating layer 115 and the fourth insulating layer 134. A bonding pad BP may be positioned at a boundary between the first stack ST1 and the second stack ST2.

In some example embodiments, the first semiconductor substrate 110 and the second semiconductor substrate 130 may include a p-type semiconductor substrate. For example, at least one of the first semiconductor substrate 110 and the second semiconductor substrate 130 may include a p-type silicon substrate. In some example embodiments, at least one of the first semiconductor substrate 110 and the second semiconductor substrate 130 may include a p-type bulk substrate and a p-type or n-type epilayer grown thereon. In some example embodiments, at least one of the first semiconductor substrate 110 and the second semiconductor substrate 130 may include an n-type bulk substrate, and a p-type or n-type epilayer grown thereon.

In some example embodiments, a pixel isolation structure 140 may be positioned in the first semiconductor substrate 110 of the first stack ST1. The plurality of pixels PX may be defined by the pixel isolation structure 140. The pixel isolation structure 140 may include a conductive layer 142, an insulating liner 144, and an upper insulating layer 146. The conductive layer 142 may be positioned inside a pixel trench penetrating the first semiconductor substrate 110. The insulating liner 144 may be disposed on an inner wall of the pixel trench penetrating the first semiconductor substrate 110 and may be positioned between the conductive layer 142 and the first semiconductor substrate 110. The upper insulating layer 146 may be positioned in a portion of the pixel trench adjacent to the front surface 110F of the first semiconductor substrate 110.

In some example embodiments, the pixel isolation structure 140 may pass through the first semiconductor substrate 110. For example, the pixel isolation structure 140 may include a front-side deep trench isolation (FDTI). Unlike shown, the pixel isolation structure 140 may not pass through the first semiconductor substrate 110. For example, the pixel isolation structure 140 may include a back-side deep trench isolation (BDTI).

In some example embodiments, the conductive layer 142 may include at least one of a doped polysilicon, a metal, a metal silicide, a metal nitride, or a metal containing film. The insulating liner 144 may include an insulating material, such as silicon oxide, silicon nitride, or silicon oxynitride. The upper insulating layer 146 may include an insulating material, such as silicon oxide, silicon nitride, or silicon oxynitride.

In some example embodiments, a plurality of photoelectric conversion regions PD may be respectively positioned in the first stack ST1 in the plurality of pixels PX. The photoelectric conversion region PD may include a region doped with n-type impurities. For example, the photoelectric conversion region PD may have a potential gradient due to an impurity concentration difference between the upper and lower portions of the photoelectric conversion region PD. Alternatively, the photoelectric conversion region PD may be formed by stacking a plurality of impurity regions in the vertical direction (Z).

Optionally, a liner region 148 surrounding each of the plurality of photoelectric conversion regions PD may be positioned in a portion of the first semiconductor substrate 110. The liner region 148 may be positioned between the pixel isolation structure 140 and the photoelectric conversion region PD and may include a region doped with p-type impurities.

In some example embodiments, the floating diffusion region FD may be positioned in an inner region of the first semiconductor substrate 110 adjacent to the front surface 110F of the first semiconductor substrate 110. The floating diffusion region FD may include a region in which charges transferred from the photoelectric conversion region PD are stored. A ground region (not shown) may be positioned in the inner region of the first semiconductor substrate 110 adjacent to the front surface 110F of the first semiconductor substrate 110. In some example embodiments, when two photoelectric conversion regions PD are positioned in one pixel PX, the floating diffusion region FD may be shared by the two photoelectric conversion regions PD. For example, when one pixel PX includes two photoelectric conversion regions PD, the floating diffusion region FD may include a region in which charges transferred from the two photoelectric conversion regions PD of the pixel PX are stored.

In some example embodiments, a transfer transistor TX may be disposed on the front surface 110F of the first semiconductor substrate 110. The transfer transistor TX may include a transfer gate. For example, the transfer gate may include, but is not limited to, a vertical transfer gate. In some example embodiments, the transfer transistor TX may include a planar transfer gate. The transfer gate may include at least one of a doped polysilicon, a metal, a metal silicide, a metal nitride, or a metal containing film.

In some example embodiments, the transfer transistor TX may transfer the charges generated from the photoelectric conversion region PD to the floating diffusion region FD. The transfer transistor TX may electrically connect the photoelectric conversion region PD to the floating diffusion region FD.

In some example embodiments, the first insulating layer 111 may cover the transfer transistor TX and the front surface 110F of the first semiconductor substrate 110. The first insulating layer 111 may electrically isolate the plurality of transfer transistors TX from each other. The first insulating layer 111 may include a buried oxide layer (BOX). For example, the first insulating layer 111 may include silicon oxide.

In some example embodiments, the pixel transistor 120 may be positioned in each of the plurality of pixels PX within the first stack ST1. The pixel transistor 120 may be disposed on the first insulating layer 111. The pixel transistor 120 may include a thin film transistor. The pixel transistor 120 may have a gate-all-around structure but is not limited thereto.

In some example embodiments, some of a plurality of pixel transistors may be disposed on the front surface 110F of the first semiconductor substrate 110 and may be covered by the first insulating layer 111. For example, one or more pixel transistors of a source follower transistor, a selection transistor, and a reset transistor may be disposed on the front surface 110F of the first semiconductor substrate 110 and may be covered by the first insulating layer 111. One or more pixel transistors of the source follower transistor, the selection transistor, and the reset transistor may be disposed on the first insulating layer 111.

In some example embodiments, the pixel transistor 120 may include patterns 121, gate insulating films 123, and a gate electrode 125.

In some example embodiments, the patterns 121 may be spaced apart from each other in the vertical direction (Z) on the first insulating layer 111 and extend in the second direction (Y). The patterns 121 may include, but is not limited to, a polysilicon. The pattern 121 may include a pattern having a relatively large width in the first direction (X) and a relatively small thickness in the vertical direction (Z). In some example embodiments, at least one pattern 121 among the plurality of patterns 121 may have a different thickness in the vertical direction (Z) from the other patterns 121.

In some example embodiments, the number of patterns 121 included in each pixel transistor 120 may be different. As shown in FIG. 2, a first pixel transistor 120a may include two patterns 121 and a second pixel transistor 120b may include one pattern 121. For example, each pattern 121 may function as a channel region.

In some example embodiments, the gate electrode 125 may extend in the first direction (X) to surround the pattern 121. The gate electrode 125 may surround the top, side, and bottom surfaces of the pattern 121. The gate electrode 125 may be positioned between adjacent patterns 121 and between the pattern 121 and the first insulating layer 111 in the vertical direction (Z).

In some example embodiments, the gate electrode 125 may include a doped polysilicon, a metal, a conductive metal nitride, a conductive metal carbide, a conductive metal silicide, or a combination thereof. For example, the gate electrode 125 may include, but is not limited to, aluminum (Al), copper (Cu), titanium (Ti), tantalum (Ta), tungsten (W), molybdenum (Mo), tantalum nitride (TaN), nickel silicide (NiSi), cobalt silicide (CoSi), titanium nitride (TiN), tungsten nitride (WN), titanium aluminide (TiAl), titanium aluminum nitride (TiAlN), tantalum carbon nitride (TaCN), tantalum carbide (TaC), tantalum silicon nitride (TaSiN), or combinations thereof.

In some example embodiments, the gate electrode 125 may be connected to a gate contact 127. The gate contact 127 may include at least one of Cu, Al, W, Ti, TiN, Ta, TaN, ruthenium (Ru), and WN. The gate contact 127 may electrically connect the gate electrode 125 to the first wiring structure 117.

In some example embodiments, the gate insulating film 123 may be positioned between the pattern 121 and the gate electrode 125. In some example embodiments, the gate insulating film 123 may include silicon oxide, silicon oxynitride, a high dielectric material having a higher dielectric constant than silicon oxide, or a combination thereof. The high dielectric material may include a metal oxide or a metal oxynitride. For example, the high dielectric material that can be used as the gate insulating film 123 may include hafnium oxide (HfO), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO), aluminum oxide (AlO), or a combination thereof, but is not limited thereto.

In some example embodiments, by forming the pixel transistor 120 as a thin film transistor on the first insulating layer 111, the area of the photoelectric conversion region PD may be increased, compared to a comparative example, to increase the full well capacity (FWC) and the quantum effect (QE), thereby improving the characteristics of the image sensor 100. By using the pixel transistor 120 having a gate all-around structure, noise characteristics and GM characteristics of the pixel transistor 120 may be improved.

Arranging the pixel transistor 120 on the first insulating layer 111 may be advantageous in terms of leakage current (e.g., junction leakage or gate induced drain leakage (GIDL)) of the pixel transistor 120. By forming the pixel transistor 120 as a thin film transistor together with the photoelectric conversion region PD in the first stack ST1, the image sensor 100 may be formed into a two-stack structure, thereby reducing the manufacturing cost and the manufacturing time for the image sensor 100 due to the process simplification.

In some example embodiments, the pixel transistor 120 may be configured to provide signals to the photoelectric conversion region PD and the floating diffusion region FD in the first stack ST1. For example, the photoelectric conversion region PD and/or the floating diffusion region FD positioned in the first stack ST1 in one pixel PX may be electrically connected to the pixel transistor 120 positioned in the first stack ST1 in one pixel PX.

In some example embodiments, the pixel transistor 120 may include a source follower transistor, a selection transistor, and a reset transistor. The reset transistor may be configured to periodically reset the charges stored in the floating diffusion region FD. The source follower transistor may function as a source follower buffer amplifier and may be configured to buffer signals according to charges stored in the floating diffusion region FD. The selection transistor may perform switching and addressing for selecting the pixel PX.

In some example embodiments, the second insulating layer 113 may cover the first insulating layer 111 and the pixel transistor 120. The second insulating layer 113 may electrically isolate the plurality of pixel transistors 120 from each other. The second insulating layer 113 may include, for example, at least one of silicon oxide, silicon nitride, silicon oxynitride, or silicon carbon nitride.

In some example embodiments, the first stack ST1 may include a contact structure. The contact structure may include a first contact CT1 and a second contact CT2. The first contact CT1 and the second contact CT2 may pass through the first insulating layer 111 and the second insulating layer 113. The first contact CT1 may be connected to the transfer transistor TX. The second contact CT2 may be connected to the floating diffusion region FD.

In some example embodiments, the third insulating layer 115 may cover the second insulating layer 113. The third insulating layer 115 may include, for example, at least one of silicon oxide, silicon nitride, silicon oxynitride, or silicon carbon nitride.

In some example embodiments, the first wiring structure 117 may be arranged within the third insulating layer 115. The first wiring structure 117 may include a plurality of conductive vias and a plurality of wiring layers. The first wiring structure 117 may be electrically connected to the transfer transistor TX through the first contact CT1. The first wiring structure 117 may be electrically connected to the floating diffusion region FD through the second contact CT2.

A fourth insulating layer 134 and a second wiring structure 136 may be disposed on the front surface 130F of the second semiconductor substrate 130 of the second stack ST2. The fourth insulating layer 134 may include, for example, at least one of silicon oxide, silicon nitride, silicon oxynitride, or silicon carbon nitride. The second wiring structure 136 may include a plurality of conductive vias and a plurality of wiring layers. The second wiring structure 136 may be electrically connected to the logic transistors LCT. The second stack ST2 may include the logic transistors LCT disposed on the front surface 130F of the second semiconductor substrate 130, wherein the logic transistor LCT may include a logic gate LCG and source/drain regions LCS.

In some example embodiments, the first contact CT1, the second contact CT2, the first wiring structure 117, and the second wiring structure 136 may include at least one of Cu, Al, W, Ti, TiN, Ta, TaN, Ru, and WN.

In some example embodiments, the third insulating layer 115 of the first stack ST1 may face the fourth insulating layer 134 of the second stack ST2. The first wiring structure 117 of the first stack ST1 may face the second wiring structure 136 of the second stack ST2. A bonding layer BI may be positioned between the third insulating layer 115 of the first stack ST1 and the fourth insulating layer 134 of the second stack ST2. The bonding layer BI may be formed in a structure in which a plurality of insulating layers are stacked and may include, for example, at least one of silicon oxide, silicon nitride, silicon oxynitride, and silicon carbon nitride.

In some example embodiments, a bonding pad BP may be positioned at a boundary between the first stack ST1 and the second stack ST2. The bonding pad BP may be surrounded by the bonding layer BI. The bonding pad BP may include an upper pad portion in the first stack ST1 and a lower pad portion in the second stack ST2, wherein the upper pad portion and the lower pad portion may overlap with each other in the vertical direction (Z) and may be attached to each other. The bonding pad BP may include Cu. The first stack ST1 and the second stack ST2 may be stacked through the bonding pad BP by using a metal-oxide hybrid bonding method.

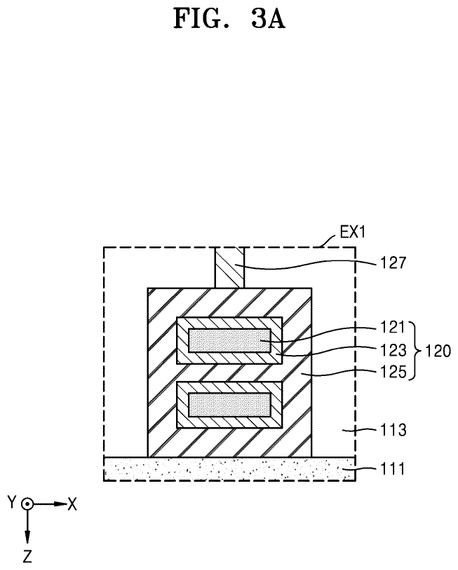

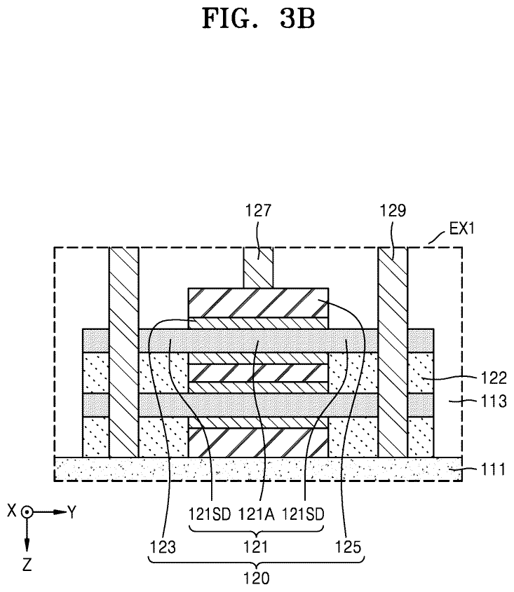

FIG. 3A is an enlarged cross-sectional view of region EX1 in FIG. 2.

FIG. 3B is an enlarged cross-sectional view taken along the center of region EX1 in FIG. 2 in the second direction (Y).

Referring to FIGS. 3A and 3B, the pixel transistor 120 may include patterns 121, gate insulating films 123, and a gate electrode 125.

In some example embodiments, the patterns 121 may be spaced apart from each other in the vertical direction (Z) on the first insulating layer 111 and extend in the second direction (Y). The pattern 121 may include a pattern having a relatively large width in the first direction (X) and a relatively small thickness in the vertical direction (Z). In some example embodiments, at least one pattern 121 among the plurality of patterns 121 may have a different thickness in the vertical direction Z from the other patterns 121.

In some example embodiments, the patterns 121 may have a line shape or a bar shape extending in the second direction (Y). Each of the patterns 121 may include a channel pattern 121A and source/drain patterns 121SD. The source/drain patterns 121SD may be connected to both ends of the channel pattern 121A. The source/drain patterns 121SD may be spaced apart from each other in the second direction (Y) with the channel pattern 121A therebetween. For example, the pattern 121 may include a polysilicon. The channel pattern 121A may include p-type impurities (e.g., boron, gallium, or indium). The source/drain patterns 121SD may include n-type impurities (e.g., phosphorus, arsenic, or antimony).

In some example embodiments, the patterns 121 may be spaced apart from each other in the vertical direction (Z). For example, the channel patterns 121A may be spaced apart from each other in the vertical direction (Z), wherein the gate electrode 125 may be positioned between the channel patterns 121A. In FIGS. 3A and 3B, the pixel transistor 120 is shown to include two patterns 121 but is not limited thereto. For example, the pixel transistor 120 may include three or more patterns 121.

In some example embodiments, the gate electrode 125 may extend in the first direction (X) to surround the patterns 121. The gate electrode 125 may surround the top, side, and bottom surfaces of the pattern 121. The gate electrode 125 may be positioned between adjacent patterns 121 and between the pattern 121 and the first insulating layer 111 in the vertical direction (Z). For example, the gate electrode 125 may surround the channel pattern 121A of the pattern 121. The gate electrode 125 may surround top, side and bottom surfaces of the channel pattern 121A. For example, the pixel transistor 120 may have a gate-all-around structure.

In some example embodiments, the gate electrode 125 may include a doped polysilicon, a metal, a conductive metal nitride, a conductive metal carbide, a conductive metal silicide, or a combination thereof. For example, the gate electrode 125 may include, but is not limited to, Al, Cu, Ti, Ta, W, Mo, TaN, NiSi, CoSi, TiN, WN, TiAl, TiAlN, TaCN, TaC, TaSiN, or a combination thereof.

In some example embodiments, the gate insulating film 123 may be positioned between the pattern 121 and the gate electrode 125. For example, the gate insulating film 123 may be positioned between the channel pattern 121A of the pattern 121 and the gate electrode 125. In some example embodiments, the gate insulating film 123 may include silicon oxide, silicon oxynitride, a high dielectric material having a higher dielectric constant than silicon oxide, or a combination thereof. The high dielectric material may include a metal oxide or a metal oxynitride. For example, the high dielectric material that can be used as the gate insulating film 123 may include HfO, HfSIO, HfSION, HfTaO, HfTIO, HfZrO, ZrO, AlO, or a combination thereof, but is not limited thereto.

In some example embodiments, the pixel transistor 120 may include sacrificial patterns 122. The sacrificial patterns 122 may be spaced apart from each other in the vertical direction (Z). For example, the sacrificial patterns 122 may be positioned between first insulating layer 111 and the pattern 121 and between adjacent patterns 121. The sacrificial patterns 122 may overlap with the source/drain patterns 121SD of the pattern 121 in the vertical direction (Z). The sacrificial patterns 122 may cross the source/drain patterns 121SD in the vertical direction (Z). The sacrificial patterns 122 may include, but is not limited to, silicon germanium (SiGe).

In some example embodiments, the gate electrode 125 may be connected to the gate contact 127. The gate contact 127 may be in contact with the top surface of the gate electrode 125. Source/drain contacts 129 may be connected to the source/drain patterns 121SD. The source/drain contacts 129 may pass through the source/drain patterns 121SD and the sacrificial patterns 122 in the vertical direction (Z) to be in contact with the top surface of the first insulating layer 111. The source/drain contacts 129 may be connected in parallel with the source/drain patterns 121SD spaced apart from each other in the vertical direction (Z).

In some example embodiments, the gate contact 127 and the source/drain contacts 129 may include at least one of Cu, Al, W, Ti, TiN, Ta, TAN, Ru, and WN. The gate contact 127 may electrically connect the gate electrode 125 to the first wiring structure 117. The source/drain contacts 129 may electrically connect the source/drain patterns 121SD to the first wiring structure 117.

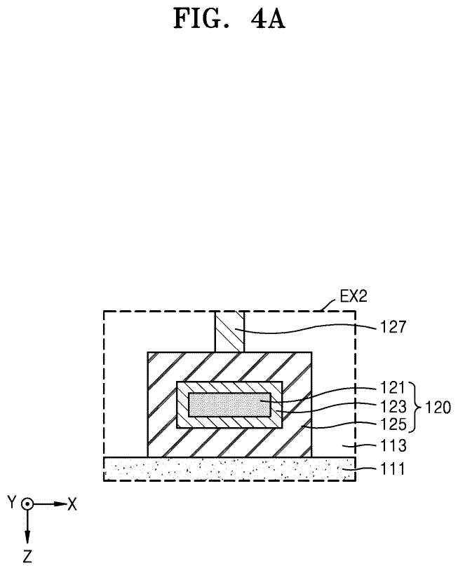

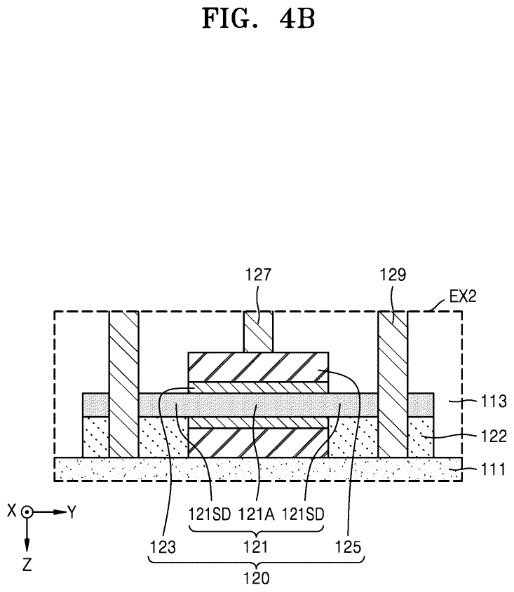

FIG. 4A is an enlarged cross-sectional view of region EX2 in FIG. 2.

FIG. 4B is an enlarged cross-sectional view taken along the center of region EX2 in FIG. 2 in the second direction (Y).

In describing FIGS. 4A and 4B, the same reference numerals as in FIGS. 1 to 3B indicate the same components and redundant description thereof is omitted.

Referring to FIGS. 4A and 4B, the pixel transistor 120 may include one pattern 121. The pattern 121 may be positioned above the first insulating layer 111 and extend in the second direction (Y). The pattern 121 may have a line shape or a bar shape extending in the second direction (Y). The pattern 121 may include a channel pattern 121A and source/drain patterns 121SD. The source/drain patterns 121SD may be connected to both ends of the channel pattern 121A. The source/drain patterns 121SD may be spaced apart from each other in the second direction (Y) with the channel pattern 121A therebetween.

In some example embodiments, the gate electrode 125 may extend in the first direction (X) to surround the pattern 121. The gate electrode 125 may surround the top, side, and bottom surfaces of the pattern 121. The gate electrode 125 may be positioned between the pattern 121 and the first insulating layer 111. For example, the gate electrode 125 may surround the channel pattern 121A of the pattern 121. The gate electrode 125 may surround top, side and bottom surfaces of the channel pattern 121A. For example, the pixel transistor 120 may have a gate-all-around structure.

In some example embodiments, the gate insulating film 123 may be positioned between the pattern 121 and the gate electrode 125. For example, the gate insulating film 123 may be positioned between the channel pattern 121A of the pattern 121 and the gate electrode 125.

In some example embodiments, the pixel transistor 120 may include a sacrificial pattern 122. The sacrificial pattern 122 may be positioned between the first insulating layer 111 and the pattern 121. The sacrificial pattern 122 may overlap with the source/drain patterns 121SD of the pattern 121 in the vertical direction (Z).

In some example embodiments, the gate electrode 125 may be connected to the gate contact 127. The gate contact 127 may be in contact with the top surface of the gate electrode 125. The source/drain contacts 129 may be connected to the source/drain patterns 121SD. The source/drain contacts 129 may pass through the source/drain patterns 121SD and the sacrificial pattern 122 in the vertical direction (Z) to be in contact with the top surface of the first insulating layer 111.

Referring to FIGS. 2 to 4B, the pixel transistor 120 may include different kinds of pixel transistors. For example, the number of patterns 121 included in the first pixel transistor 120a may be different from the number of patterns 121 included in the second pixel transistor 120b. The first pixel transistor 120a may include two patterns 121 and the second pixel transistor 120b may include one pattern 121. By adjusting the number of patterns 121 included in each of the plurality of pixel transistors 120, the width of the pixel transistors 120 in the horizontal direction may be increased, thereby improving the characteristics of the pixel transistors 120.

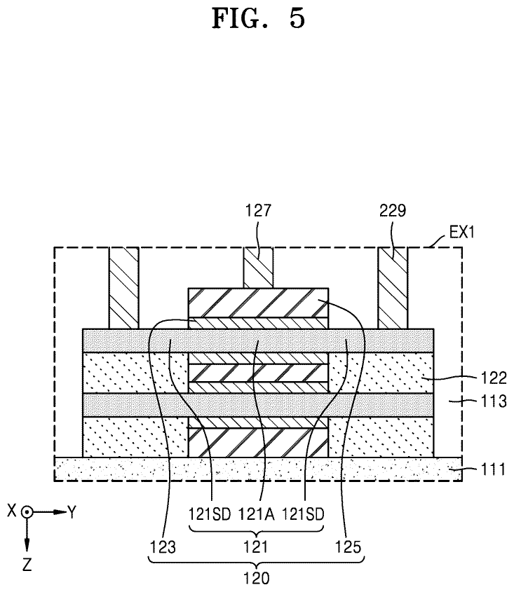

FIG. 5 is an enlarged cross-sectional view taken along the center of region EX1 in FIG. 2 in the second direction (Y).

In describing FIG. 5, the same reference numerals as in FIGS. 1 to 3B indicate the same components and redundant description thereof is omitted.

Referring to FIG. 5, the gate electrode 125 may be connected to the gate contact 127. The gate contact 127 may be in contact with the top surface of the gate electrode 125. Source/drain contacts 229 may be connected to the source/drain patterns 121SD. The source/drain contacts 229 may be in contact with a top surface of a top source/drain pattern 121SD. The source/drain contacts 229 may be connected to the top source/drain pattern 121SD and resistively connected to the other source/drain pattern 121SD.

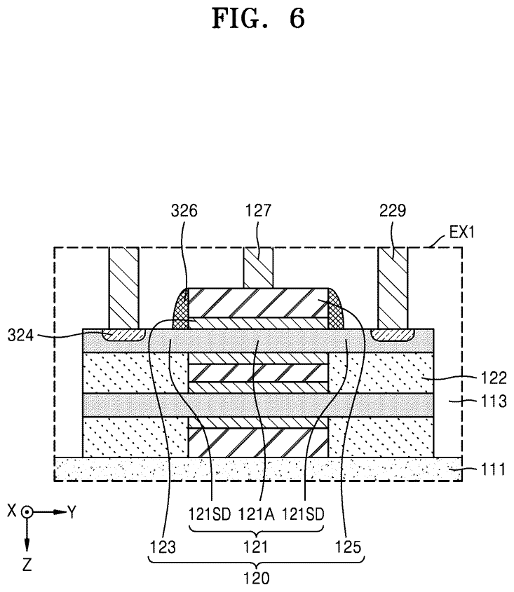

FIG. 6 is an enlarged cross-sectional view taken along the center of region EX1 in FIG. 2 in the second direction (Y).

In describing FIG. 6, the same reference numerals as in FIGS. 1 to 3B indicate the same components and redundant description thereof is omitted.

Referring to FIG. 6, the pixel transistor 120 may further include silicide layers 324 and spacer layers 326.

In some example embodiments, the silicide layers 324 may be formed in the top pattern 121 of the patterns 121. For example, the silicide layers 324 may be formed in the source/drain patterns 121SD of the top pattern 121.

In some example embodiments, the source/drain contacts 229 may be connected to the source/drain patterns 121SD. The silicide layers 324 may be positioned between the source/drain contact 229 and the source/drain patterns 121SD. The source/drain contact 229 may be configured to connect to the source/drain pattern 121SD via the silicide layer 324. The silicide layer 324 may include Ti, W, Ru, niobium (Nb), Mo, Hf, Ni, Co, platinum (Pt), ytterbium (Yb), terbium (Tb), dysprosium (Dy), erbium (Er), or palladium (Pd). For example, the silicide layers 324 may include titanium silicide.

In some example embodiments, the spacer layers 326 may cover sidewalls of the gate electrode 125. For example, the spacer layers 326 may cover sidewalls of the gate electrode 125 on the top pattern 121. The spacer layers 326 may cover sidewalls of the gate insulating film 123 on the top pattern 121. The spacer layers 326 may be spaced apart from each other in the second direction (Y) with the gate electrode 125 and the gate insulating film 123 therebetween. The spacer layer 326 may include an oxide film, a nitride film, or a combination thereof.

In FIG. 6, the pixel transistor 120 is shown to include both the silicide layer 324 and the spacer layer 326 but is not limited thereto. For example, the pixel transistor 120 may include only one of the silicide layer 324 and the spacer layer 326.

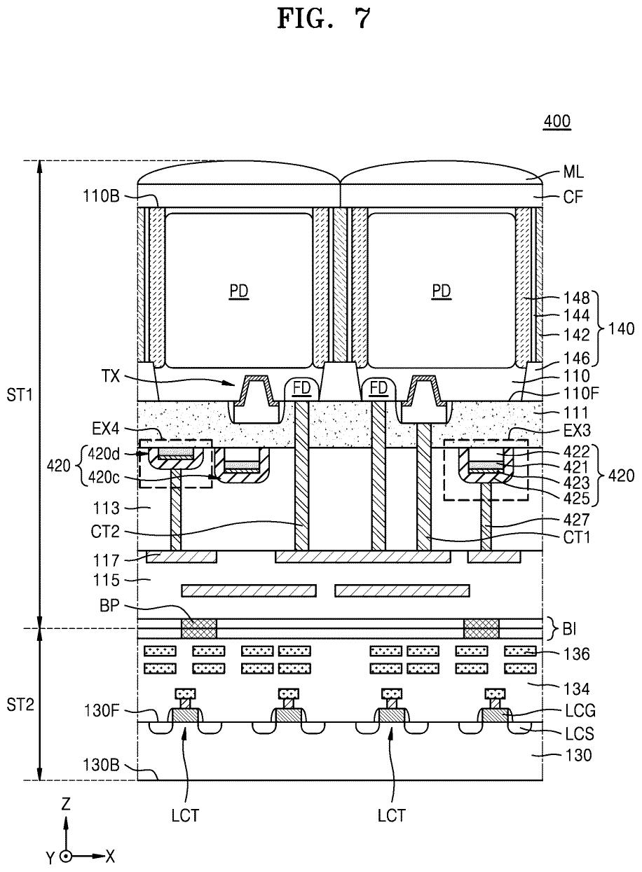

FIG. 7 is a schematic cross-sectional view of an image sensor according to some example embodiments.

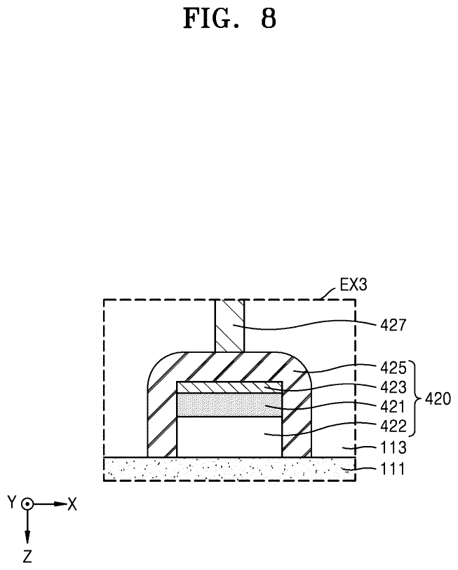

FIG. 8 is an enlarged cross-sectional view of region EX3 in FIG. 7.

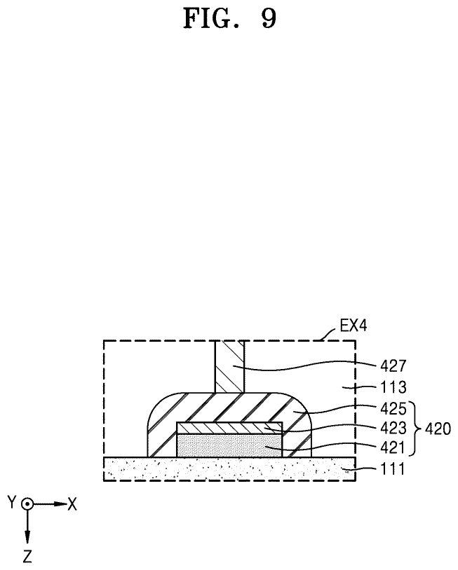

FIG. 9 is an enlarged cross-sectional view of region EX4 in FIG. 7.

In describing FIGS. 7 to 9, the same reference numerals as in FIGS. 1 to 3B indicate the same components and redundant description thereof is omitted.

Referring to FIGS. 7 to 9, an image sensor 400 may include a stacked image sensor in which the first stack ST1 and the second stack ST2 are stacked in the vertical direction (Z).

In some example embodiments, a pixel transistor 420 may be disposed on the first insulating layer 111. The pixel transistor 420 may include a thin film transistor. The pixel transistor 420 may include a third pixel transistor 420c and a fourth pixel transistor 420d. The third pixel transistor 420c and the fourth pixel transistor 420d may have a planar structure.

In some example embodiments, the third pixel transistor 420c may include a pattern 421, a gate insulating film 423, and a gate electrode 425. The pattern 421 may be positioned above the first insulating layer 111 and extend in the second direction (Y). The pattern 421 may include, but is not limited to, a polysilicon. The pattern 421 may include a pattern having a relatively large width in the first direction (X) and a relatively small thickness in the vertical direction (Z).

In some example embodiments, the pattern 421 may have a line shape or a bar shape extending in the second direction (Y). Each pattern 421 may include a channel pattern and source/drain patterns. The source/drain patterns may be connected to both ends of the channel pattern. The source/drain patterns may be spaced apart from each other in the second direction (Y) with the channel pattern therebetween. The pattern 421 may include a polysilicon. The channel pattern may include p-type impurities (e.g., boron, gallium, or indium). The source/drain patterns may include n-type impurities (e.g., phosphorus, arsenic, or antimony).

In some example embodiments, the third pixel transistor 420c may include a sacrificial pattern 422. The sacrificial pattern 422 may be positioned between the first insulating layer 111 and the pattern 421 and may extend in the second direction (Y). The sacrificial pattern 422 may overlap with the pattern 421 in the vertical direction (Z). The sacrificial pattern 422 may include, but is not limited to, SiGe.

In some example embodiments, the gate electrode 425 may cover the pattern 421 and the sacrificial pattern 422 and extend in the first direction (X). The gate electrode 425 may cover the top and side surfaces of the pattern 421. In some example embodiments, the gate electrode 425 may include a doped polysilicon, a metal, a conductive metal nitride, a conductive metal carbide, a conductive metal silicide, or a combination thereof. For example, the gate electrode 425 may include, but is not limited to, Al, Cu, Ti, Ta, W, Mo, TaN, NiSi, CoSi, TiN, WN, TiAl, TiAlN, TaCN, TaC, TaSiN, or a combination thereof. For example, the third pixel transistor 420c may have a planar structure.

In some example embodiments, the gate insulating film 423 may be positioned between the pattern 421 and the gate electrode 425. The gate insulating film 423 is positioned between the pattern 421 and the gate electrode 425 and may extend in the second direction (Y). In some example embodiments, the gate insulating film 423 may include silicon oxide, silicon oxynitride, a high dielectric material having a higher dielectric constant than silicon oxide, or a combination thereof. The high dielectric material may include a metal oxide or a metal oxynitride. For example, the high dielectric material that can be used as the gate insulating film 423 may include HfO, HfSiO, HfSION, HfTaO, HfTIO, HfZrO, ZrO, AlO, or a combination thereof, but is not limited thereto.

In some example embodiments, the gate electrode 425 may be connected to a gate contact 427. Source/drain contacts may be connected to the source/drain patterns of the pattern 421. The gate contact 427 and the source/drain contacts may include at least one of Cu, Al, W, Ti, TiN, Ta, TAN, Ru, and WN. The gate contact 427 may electrically connect the gate electrode 425 to the first wiring structure 117. The source/drain contact may electrically connect the source/drain pattern to the first wiring structure 117.

In some example embodiments, the fourth pixel transistor 420d may include a structure in which the sacrificial pattern 422 is omitted in the third pixel transistor 420c. Like the third pixel transistor 420c, the fourth pixel transistor 420d may also have a planar structure.

Referring to FIGS. 7 to 9, the pixel transistor 420 may include different kinds of pixel transistors. For example, the shape of the third pixel transistor 420c may be different from that of the fourth pixel transistor 420d. The image sensors 100 and 400 of the inventive concepts may include the first pixel transistor 120a, the second pixel transistor 120b, the third pixel transistor 420c, the fourth pixel transistor 420d, and a combination thereof described above.

In some example embodiments, by forming the pixel transistor 420 on the first insulating layer 111, the area of the photoelectric conversion region PD may be increased, compared to a comparative example, to increase the FWC and the QE, thereby improving the characteristics of the image sensor 400.

Arranging the pixel transistor 420 on the first insulating layer 111 may be advantageous in terms of leakage current (e.g., junction leakage or GIDL) of the pixel transistor 420. By forming the pixel transistor 420 together with the photoelectric conversion region PD in the first stack ST1, the image sensor 400 may be formed into a two-stack structure, thereby reducing the manufacturing cost and the manufacturing time for the image sensor 400 due to the process simplification.

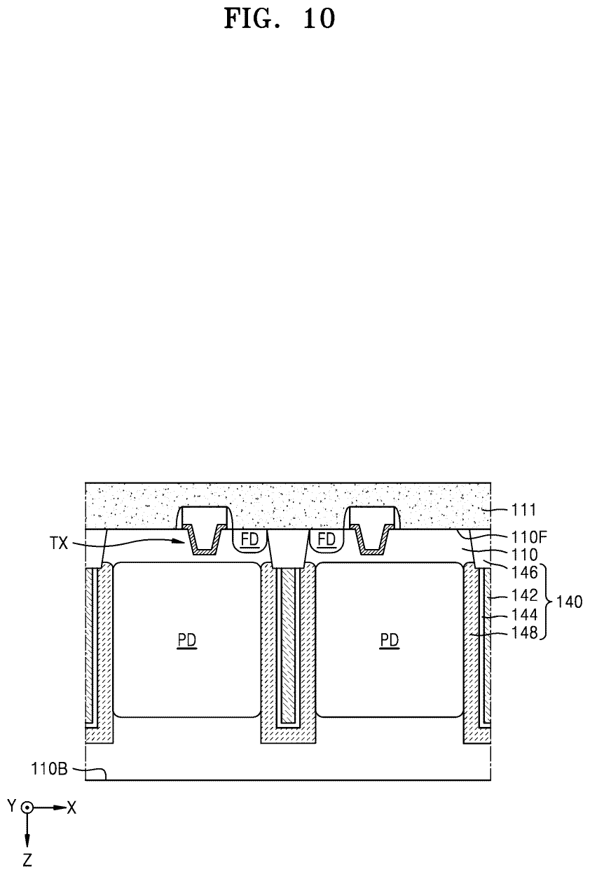

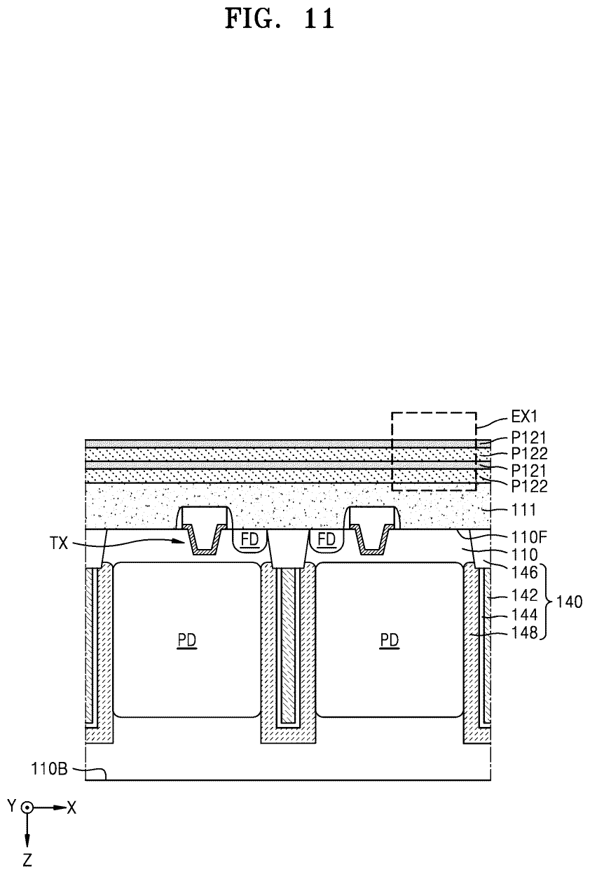

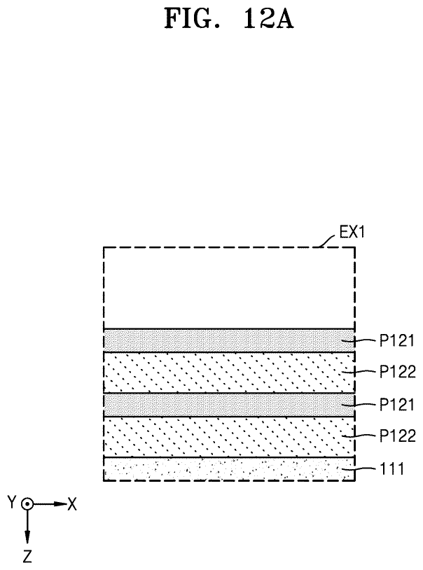

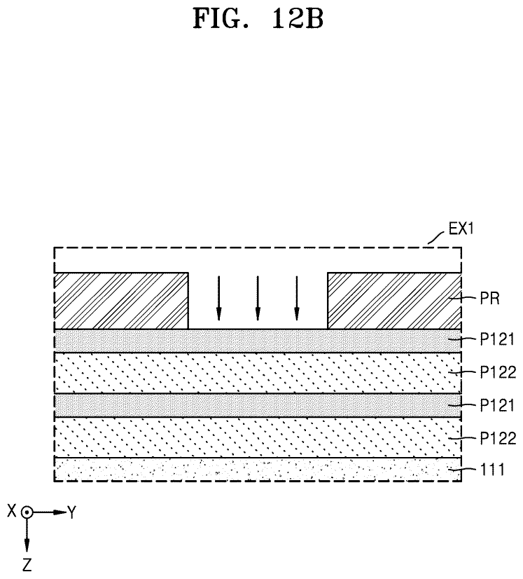

FIGS. 10 to 18 are cross-sectional views illustrating a method of manufacturing an image sensor, according to some example embodiments, wherein FIGS. 12A, 13A, 14A and 15A are enlarged cross-sectional views of region EX1 in FIG. 11 and FIGS. 12B, 13B, 14B, and 15B are enlarged cross-sectional views taken along the center of region EX1 in FIG. 11 in the second direction (Y).

Referring to FIG. 10, prepared is a first semiconductor substrate 110 having a front surface 110F and a second surface 110B, which are opposite to each other. Thereafter, a mask pattern (not shown) may be formed on the front surface 110F of the first semiconductor substrate 110 and the mask pattern may be used as an etching mask to form a pixel trench in the first semiconductor substrate 110. The pixel trench may have a certain (e.g., desired and/or predetermined) depth from the front surface 110F and may be formed in a matrix shape in a plan view.

Thereafter, an insulating liner 144 may be conformally formed on the inner wall of the pixel trench by a chemical vapor deposition (CVD) process or an atomic layer deposition (ALD) process. A conductive layer 142 filling the inner wall of the pixel trench may then be formed on the insulating liner 144. The conductive layer 142 may include at least one of a doped polysilicon, a metal, a metal silicide, a metal nitride, or a metal-containing film.

Thereafter, the upper portion of the conductive layer 142 may be removed by an etch back process so that the top surface of the conductive layer 142 reaches a lower level than the top surface of the front surface 110F of the first semiconductor substrate 110. An insulating layer (not shown) may be filled to fill the entrance of the pixel trench and may be removed so that the top surface of the first semiconductor substrate 110 is exposed, leaving an upper insulating layer 146 within the entrance of the pixel trench.

Optionally, a liner region 148 surrounding each of the plurality of photoelectric conversion regions PD may then be formed in a portion of the first semiconductor substrate 110. The liner region 148 may be positioned between the pixel isolation structure 140 and the photoelectric conversion region PD and may include a region doped with p-type impurities.

Thereafter, a floating diffusion region FD may be formed on the front surface 110F of the first semiconductor substrate 110 by an ion implantation process. For example, the floating diffusion region FD may be formed by doping n-type impurities.

A transfer transistor TX may then be formed on the front surface 110F of the first semiconductor substrate 110. The transfer transistor TX may include, but is not limited to, a vertical transfer gate. In some example embodiments, the transfer transistor TX may include a planar transfer gate. The transfer transistor TX may be formed adjacent to the floating diffusion region FD.

Then, the first insulating layer 111 may be formed to cover the transfer transistor TX and the front surface 110F of the first semiconductor substrate 110. The first insulating layer 111 may be deposited to cover the transfer transistor TX and the front surface 110F of the first semiconductor substrate 110 and a planarization process may be performed. In some example embodiments, one or more pixel transistors among the plurality of pixel transistors together with the transfer transistor TX may be disposed on the front surface 110F of the first semiconductor substrate 110 and may be covered by the first insulating layer 111.

Referring to FIG. 11, a sacrificial layer P122 and a semiconductor layer P121 may be stacked on the first insulating layer 111. The sacrificial layer P122 and the semiconductor layer P121 may be alternately stacked. In FIG. 11, the sacrificial layer P122 and the semiconductor layer P121 are each shown as including two layers but are not limited thereto. For example, the sacrificial layer P122 and the semiconductor layer P121 may each include one layer, or the sacrificial layer P122 or the semiconductor layer P121 may each include three or more layers.

In some example embodiments, the sacrificial layer P122 and the semiconductor layer P121 may be formed of a material having an etch selectivity with respect to each other. For example, the sacrificial layer P122 may include SiGe and the semiconductor layer P121 may include a polysilicon.

In some example embodiments, the sacrificial layer P122 and the semiconductor layer P121 may be formed by a CVD process, such as vapor-phase epitaxy (VPE), ultra-high vacuum chemical vapor deposition (UHV-CVD), or the like, molecular beam epitaxy, or a combination thereof. A liquid or gas phase precursor may be used as a precursor required for formation of the sacrificial layer P122 and the semiconductor layer P121.

After the sacrificial layer P122 and the semiconductor layer P121 are formed, a solid-phase crystallization (SPC) process may be performed. Through SPC, the grain sizes of the sacrificial layer P122 and the semiconductor layer P121 may be adjusted while reducing and/or minimizing lattice mismatch between the sacrificial layer P122 and the semiconductor layer P11.

Referring to FIGS. 12A and 12B, a first mask pattern PR may be formed on the semiconductor layer P121. The first mask pattern PR may expose a partial region of the semiconductor layer P121. For example, the first mask pattern PR may expose a region of the semiconductor layer P121 where the channel pattern 121A (see FIG. 3B) will be formed. The channel pattern 121A may be formed by injecting p-type impurities (e.g., boron, gallium, or indium) into the semiconductor layer P121 through a portion exposed by the first mask pattern PR.

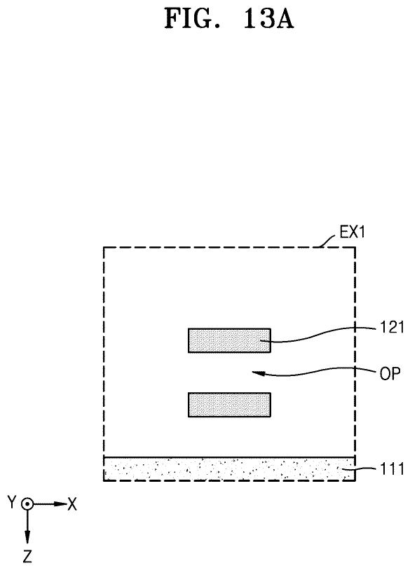

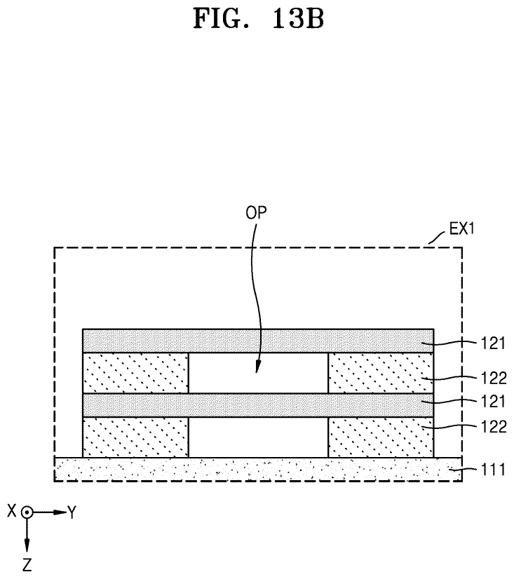

Referring to FIGS. 13A and 13B, the first mask pattern PR may be removed and a second mask pattern (not shown) may be formed on the semiconductor layer P121. The size of the pixel transistor may be defined by etching partial regions of the sacrificial layer P122 and the semiconductor layer P121 through the second mask pattern. The partial regions of the sacrificial layer P122 and the semiconductor layer P121 may be etched to form the sacrificial pattern 122 and the pattern 121.

The second mask pattern may then be removed and a third mask pattern covering partial regions of the sacrificial pattern 122 and the pattern 121 may be formed. The third mask pattern may expose partial regions of the sacrificial pattern 122 and the pattern 121. A gate space OP may be formed through the portion exposed by the third mask pattern. The gate space OP may be formed between the pattern 121 and the first insulating layer 111 and between adjacent patterns 121 in the vertical direction (Z). The process of forming the gate space OP may include a wet etch process using an etch selectivity between the sacrificial pattern 122 and the pattern 121.

In some example embodiments, the gate space OP may overlap with a partial region of the pattern 121 in the vertical direction (Z). In a region where the gate space OP is not formed, the pattern 121 may overlap with the sacrificial pattern 122 in the vertical direction (Z).

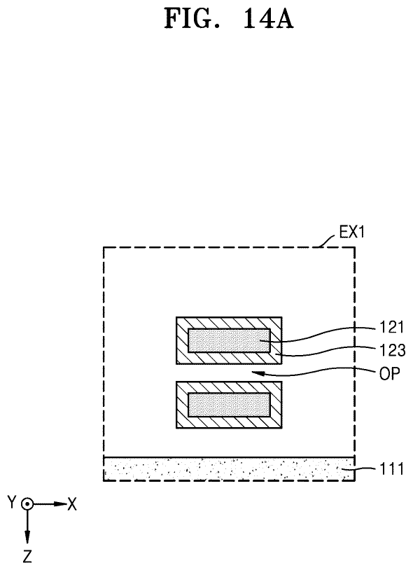

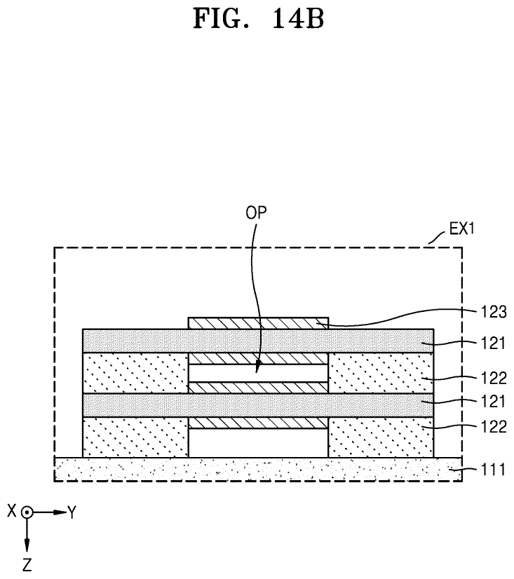

Referring to FIGS. 14A and 14B, a gate insulating film 123 may be formed. The gate insulating film 123 may be formed to surround a partial region of the pattern 121 while filling a portion of the gate space OP. The gate insulating film 123 may conformally cover the top, side, and bottom surfaces of the pattern 121.

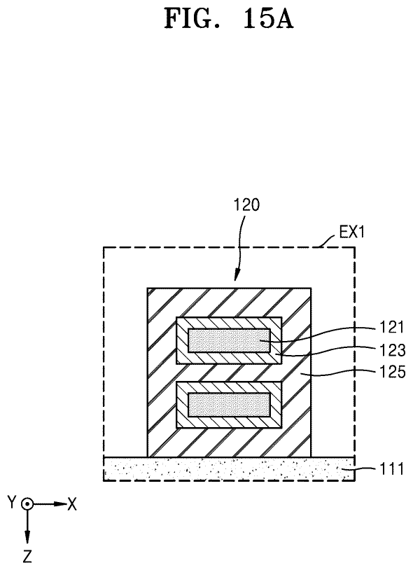

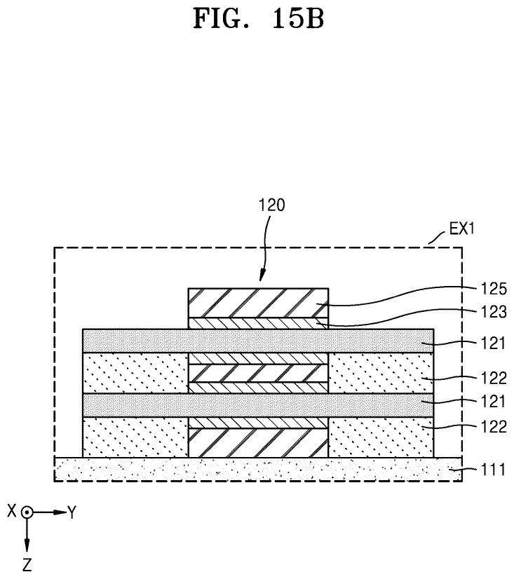

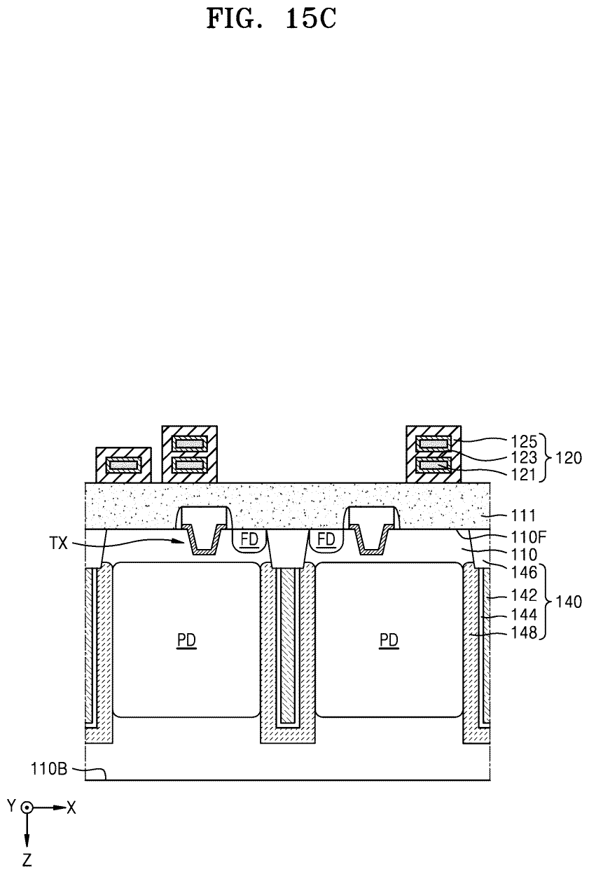

Referring to FIGS. 15A, 15B, and 15C, a gate electrode 125 may be formed. The gate electrode 125 may be formed to fill the gate space OP and surround the patterns 121. The gate electrode 125 may surround the top, side, and bottom surfaces of the pattern 121. The gate electrode 125 may be positioned between adjacent patterns 121 and between the pattern 121 and the first insulating layer 111 in the vertical direction (Z).

Thereafter, n-type impurities (e.g., phosphorus, arsenic, or antimony) may be injected into a region of the pattern 121 that does not overlap with the gate electrode 125 to form the source/drain patterns 121SD (see FIG. 3B), whereby the pixel transistor 120 may be formed on the first insulating layer 111.

In some example embodiments, referring to FIGS. 7 and 8, after the sacrificial pattern 422 and the pattern 421 extending in the second direction (Y) are formed on the first insulating layer 111, the gate electrode 425 covering the pattern 421 and the sacrificial pattern 422 and extending in the first direction (X) may be formed without forming the gate space OP, thereby forming the pixel transistor 420a having a planar structure.

In some example embodiments, referring to FIGS. 7 and 9, after the pattern 421 extending in the second direction (Y) is formed on the first insulating layer 111, the gate electrode 425 covering the pattern 421 and extending in the first direction (X) may be formed without forming the gate space OP, and accordingly, the pixel transistor 420b has a planar structure.

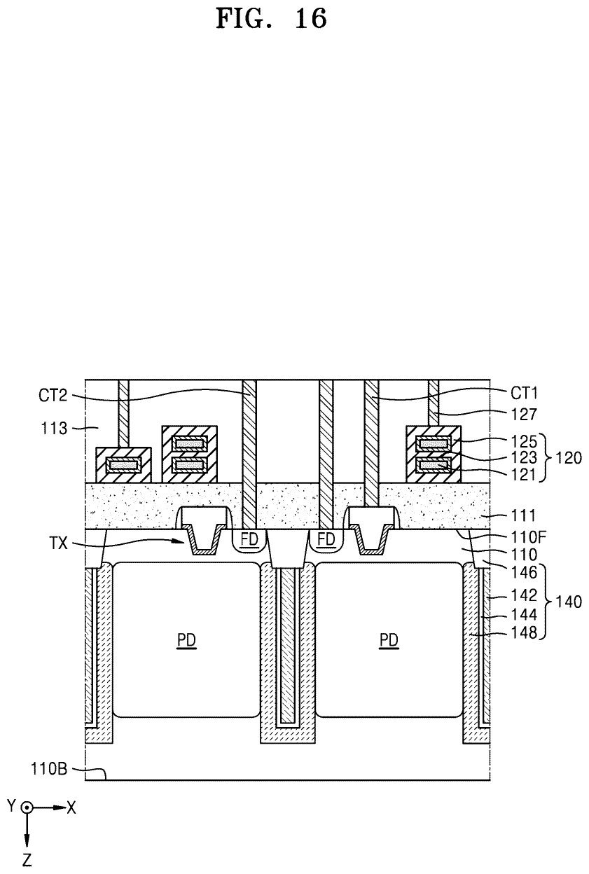

Referring to FIG. 16, a second insulating layer 113 covering the pixel transistor 120 and the first insulating layer 111 may be formed. A first contact CT1, a second contact CT2, a gate contact 127, and source/drain contacts 129 (see FIG. 3B) penetrating the second insulating layer 113 may be formed. The first contact CT1 may be connected to the transfer transistor TX and the second contact CT2 may be connected to the floating diffusion region FD. The gate contact 127 may be connected to the gate electrode 125 and the source/drain contacts 129 may be connected to the source/drain patterns 121SD (see FIG. 3B). The source/drain contacts 129 may pass through the source/drain patterns 121SD (see FIG. 3B) and the sacrificial patterns 122 (see FIG. 3B) in the vertical direction (Z) to be in contact with the top surface of the first insulating layer 111. In some example embodiments, the source/drain contacts 229 (see FIG. 5) may be in contact with the top surface of the top source/drain pattern 121SD.

In some example embodiments, the silicide layers 324 (see FIG. 6) and/or the spacer layers 326 (see FIG. 5) may be formed prior to forming the second insulating layer 113. Thereafter, the second insulating layer 113 covering the silicide layers 324 and/or the spacer layers 326 may be formed, and the first contact CT1, the second contact CT2, the gate contact 127, and the source/drain contacts 129, each passing through the second insulating layer 113, may be formed.

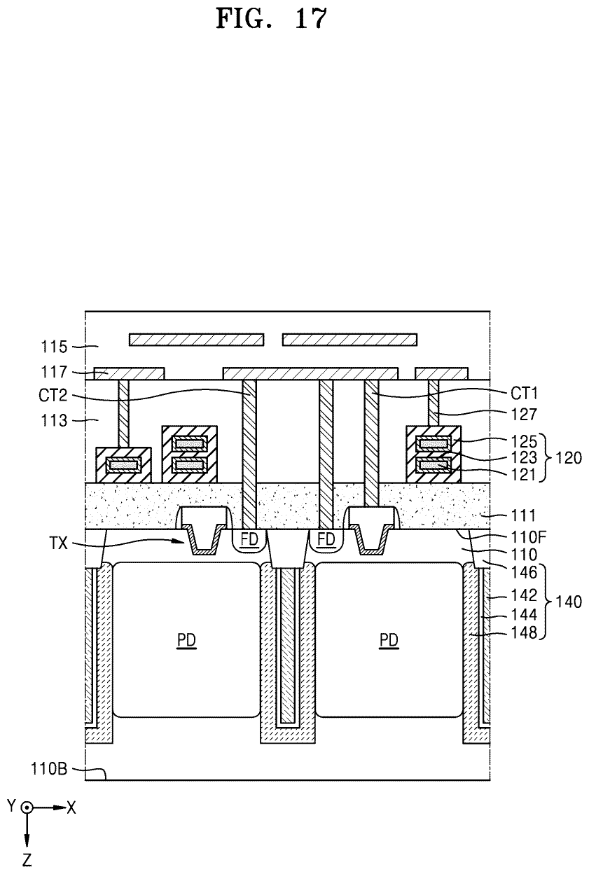

Referring to FIG. 17, a third insulating layer 115 and a first wiring structure 117 may be formed on the second insulating layer 113. The first wiring structure 117 may be arranged within the third insulating layer 115. The first wiring structure 117 may include a plurality of conductive vias and a plurality of wiring layers. The first wiring structure 117 may be electrically connected to the transfer transistor TX through the first contact CT1 and may be electrically connected to the floating diffusion region FD through the second contact CT2. The first wiring structure 117 may be electrically connected to the gate electrode 125 through the gate contact 127 and may be electrically connected to the source/drain patterns 121SD through the source/drain contacts 129.

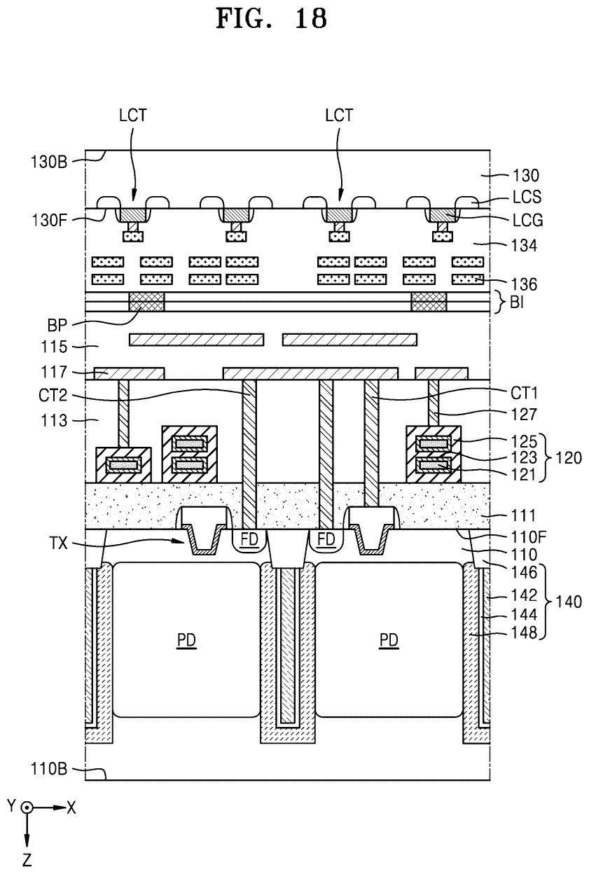

Referring to FIG. 18, the second stack ST2 (see FIG. 3) may be attached to the first stack ST1 (see FIG. 2).

The second stack ST2 may include a second semiconductor substrate 130 having a front surface 130F, a bottom surface 130B, and logic transistors LCT, a second wiring structure 136, and a fourth insulating layer 134, each disposed on the front surface 130F of the second semiconductor substrate 130.

Thereafter, the second stack ST2 may be attached on the first stack ST1 with the bonding layer BI therebetween. The third insulating layer 115 of the first stack ST1 and the fourth insulating layer 134 of the second stack ST2 may be attached to face each other. The second stack ST2 may be attached to the first stack ST1 with the logic transistors LCT formed on the second semiconductor substrate 130.

The bonding pad BP may include an upper pad portion in the first stack ST1 and a lower pad portion in the second stack ST2, wherein the upper pad portion and the lower pad portion may overlap with each other in the vertical direction (Z) and may be attached to each other. For example, the first stack ST1 and the second stack ST2 may be stacked by a metal-oxide hybrid bonding method.

Referring again to FIG. 2, the stacked structure may be flipped such that the back surface 110B of the first semiconductor substrate 110 faces upward. A portion of the first semiconductor substrate 110 may then be removed from the back surface 110B of the first semiconductor substrate 110 through a planarization process, such as a CMP process or an etch back process, so that the top surface (e.g., an end adjacent to the back surface 110B of the first semiconductor wafer 110) of the pixel isolation structure 140 is exposed.

Although not shown, a backside insulating layer (not shown) may be formed on the back surface 110B of the first semiconductor substrate 110. The backside insulating layer may include a metal oxide and may function as a negative charge fixing layer. Thereafter, the image sensor 100 may be completed by forming a color filter CF and a microlens ML on the back surface 110B of the first semiconductor substrate 110 in the active pixel region APR.

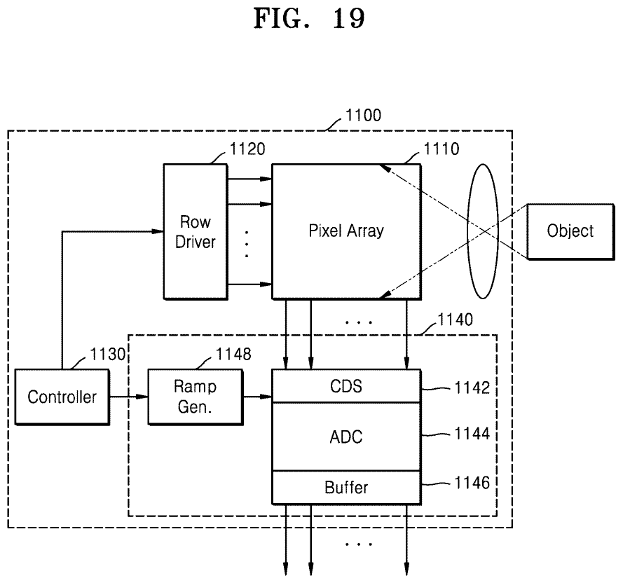

FIG. 19 is a block diagram showing the configuration of an image sensor 1100 according to some example embodiments.

Referring to FIG. 19, the image sensor 1100 may include a pixel array 1110, a controller 1130, a row driver 1120, and a pixel signal processing unit 1140. The image sensor 1100 includes at least one of the image sensors 100 and 400 described with reference to FIGS. 1 to 18 as part of pixel array 1110 for example.

The pixel array 1110 may include a plurality of unit pixels arranged in two dimensions, wherein each unit pixel may include a photoelectric conversion element. The photoelectric conversion element may absorb light to generate charges and electrical signals (output voltage) according to the generated charges may be provided to the pixel signal processing unit 1140 through a vertical signal line. The unit pixels included in the pixel array 1110 may provide an output voltage one at a time in rows so that the unit pixels belonging to one row of the pixel array 1110 may be simultaneously activated by a selection signal output by the row driver 1120. The unit pixels belonging to the selected row may provide an output voltage in accordance with the absorbed light to the output line of the corresponding column.

The controller 1130 may control the row driver 1120 to cause the pixel array 1110 to absorb light to accumulate charges, temporarily store the accumulated charges, and output electrical signals according to the stored charges to the outside of the pixel array 1120. Furthermore, the controller 1130 may control the pixel signal processing unit 1140 to measure the output voltage provided by the pixel array 1110.

The pixel signal processing unit 1140 may include a CDS 1142, an analog-to-digital converter (ADC) 1144, and a buffer 1146. The CDS 1142 may sample and hold the output voltage provided by the pixel array 1110. The CDS 1142 may double-sample a specific noise level and a level according to the generated output voltage and may output a level corresponding to the difference. The CDS 1142 may receive ramp signals generated by the ramp signal generator 1148 and compare the ramp signals with each other to output a comparison result.

The ADC 1144 may convert an analog signal corresponding to the level received from the CDS 1142 into a digital signal. The buffer 1146 may latch the digital signal, wherein the latched signal may be sequentially output to the outside of the image sensor 1100 and transmitted to an image processor (not shown).

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. An image sensor comprising:
a first semiconductor substrate;
a photoelectric conversion region within the first semiconductor substrate;
a floating diffusion region within the first semiconductor substrate, the floating diffusion region configured to store charges transferred from the photoelectric conversion region;
a transfer transistor on a front surface of the first semiconductor substrate, the transfer transistor configured to electrically connect the photoelectric conversion region to the floating diffusion region;
a first insulating layer covering the front surface of the first semiconductor substrate and the transfer transistor; and
a pixel transistor on the first insulating layer, wherein the pixel transistor comprises a thin film transistor.

2. The image sensor of claim 1, wherein the pixel transistor further comprises:
patterns spaced apart from each other in a vertical direction on the first insulating layer, the patterns comprising a channel pattern and source/drain patterns connected to the channel pattern;
a gate electrode surrounding the patterns; and
a gate insulating film between the patterns and the gate electrode.

3. The image sensor of claim 2, wherein the pixel transistor further comprises a sacrificial pattern between the first insulating layer and the patterns, and between adjacent patterns of the patterns.

4. The image sensor of claim 3, further comprising:
a gate contact connected to the gate electrode; and
source/drain contacts connected to source/drain patterns of a top pattern of the patterns.

5. The image sensor of claim 3, further comprising:
a gate contact connected to the gate electrode; and
source/drain contacts penetrating the patterns and the sacrificial pattern in the vertical direction.

6. The image sensor of claim 5, wherein the pixel transistor further comprises a silicide layer between the source/drain patterns of a top pattern of the patterns and the source/drain contacts.

7. The image sensor of claim 5, wherein the pixel transistor further comprises a spacer layer covering a sidewall of the gate electrode.

8. The image sensor of claim 3, wherein the patterns comprise polysilicon, and the sacrificial pattern comprises silicon germanium.

9. The image sensor of claim 1, wherein the pixel transistor further comprises:
a pattern on the first insulating layer and including a channel pattern and source/drain patterns connected to the channel pattern; and
a gate electrode covering a top surface of the pattern.

10. An image sensor comprising:
a first semiconductor substrate;
a photoelectric conversion region within the first semiconductor substrate;
a floating diffusion region within the first semiconductor substrate, the floating diffusion region configured to store charges transferred from the photoelectric conversion region;
a transfer transistor on a front surface of the first semiconductor substrate, the transfer transistor configured to electrically connect the photoelectric conversion region to the floating diffusion region;
a first insulating layer covering the front surface of the first semiconductor substrate and the transfer transistor; and
a plurality of pixel transistors on the first insulating layer, the plurality of pixel transistors each consisting of a thin film transistor,
wherein the plurality of pixel transistors comprise a first pixel transistor and a second pixel transistor, and wherein the first pixel transistor and the second pixel transistor are different types of pixel transistors.

11. The image sensor of claim 10, wherein the first pixel transistor comprises a gate all-around thin film transistor, and the second pixel transistor comprises a thin film transistor having a planar structure.

12. The image sensor of claim 10, wherein the first pixel transistor comprises:
first patterns spaced apart from each other in a vertical direction on the first insulating layer, the first patterns including a first channel pattern and first source/drain patterns connected to the first channel pattern; and
a first gate electrode surrounding the first patterns,
wherein the second pixel transistor comprises
second patterns spaced apart from each other in the vertical direction on the first insulating layer, the second patterns including a second channel pattern and second source/drain patterns connected to the second channel pattern, and
a second gate electrode surrounding the second patterns,
wherein a number of first patterns is different from a number of second patterns.

13. The image sensor of claim 12, wherein
the first pixel transistor further comprises a first sacrificial pattern between the first insulating layer and the first patterns, and between adjacent first patterns of the first patterns, and
the second pixel transistor comprises a second sacrificial pattern between the first insulating layer and the second patterns, and between adjacent second patterns of the second patterns.

14. The image sensor of claim 13, wherein the first patterns and the second patterns comprise polysilicon, and the first sacrificial pattern and the second sacrificial pattern comprise silicon germanium.

15. An image sensor comprising:
a first stack comprising
a first semiconductor substrate including a first surface and a second surface opposite the first surface,
a photoelectric conversion region in the first semiconductor substrate, a floating diffusion region arranged in the first semiconductor substrate, the floating diffusion region configured to store charges transferred from the photoelectric conversion region,
a transfer transistor on a front surface of the first semiconductor substrate, the transfer transistor configured to electrically connect the photoelectric conversion region to the floating diffusion region,
a first insulating layer covering the front surface of the first semiconductor substrate and the transfer transistor, and
a pixel transistor on the first insulating layer; and
a second stack attached to the first stack, the first stack comprising a logic transistor configured to provide signals to the pixel transistor and the transfer transistor,
wherein the pixel transistor comprises a thin film transistor including polysilicon.

16. The image sensor of claim 15, wherein the pixel transistor further comprises:
patterns spaced apart from each other in a vertical direction on the first insulating layer, the patterns comprising a channel pattern and source/drain patterns connected to the channel pattern;
a gate electrode surrounding the patterns; and
a gate insulating film between the patterns and the gate electrode.

17. The image sensor of claim 16, wherein the first stack further comprises:
a gate contact connected to the gate electrode; and
source/drain contacts connected to the source/drain patterns.

18. The image sensor of claim 17, wherein the first stack further comprises:
a second insulating layer covering the pixel transistor;
a first contact penetrating the first and second insulating layers, the first contact being connected to the transfer transistor;
a second contact penetrating the first and second insulating layers, the second contact being connected to the floating diffusion region;
a third insulating layer covering the second insulating layer; and
a first wiring structure inside the third insulating layer.

19. The image sensor of claim 16, wherein
the pixel transistor further comprises a sacrificial pattern between the first insulating layer and the patterns, and between adjacent patterns of the patterns, and
the sacrificial pattern comprises silicon germanium.

20. The image sensor of claim 15, wherein the pixel transistor further comprises:
a pattern on the first insulating layer, the pattern including polysilicon, and the pattern including a channel pattern and source/drain patterns connected to the channel pattern; and
a gate electrode covering a top surface of the pattern.
